(19) United States
(12) Patent Application Publication
(10) Pub. No.: US 2012/0125408 A1
(43) Pub. Date: May 24, 2012

(54) SOLAR PANEL RACKING ASSEMBLY AND SYSTEM

(76) Inventors: Rene Reyes, Saddle Brook, NJ (US); Michael Murphy, (US)

(21) Appl. No.: 13/195,110

(22) Filed: Aug. 1, 2011

Related U.S. Application Data
(60) Provisional application No. 61/369,425, filed on Jul. 30, 2010.

(51) Int. Cl. H01L 31/048; H01L 23/32

(52) U.S. Cl. 136/251; 211/41.1

(57) ABSTRACT

A racking system for a solar panel includes a solar panel support rack assembly, the solar panel support rack assembly being configured to be coupled to another solar panel support rack assembly. Each solar panel support rack assembly includes a first arm having a first end and a second end, the first arm configured to be coupled to a base structure, a second arm having a first end and a second end, the first end of the second arm coupled to the first end of the first arm, the second arm being disposed at an angle from the first arm, and a third arm having a first end and a second end, the first end of the third arm coupled to the second end of the first arm and the second end of the third arm coupled to the second end of the second arm. The second arm includes a first channel member and a second channel member, the first and second channel members being disposed on opposing sides of the second arm, and a stop member at the first end.

### CROSS-REFERENCE TO RELATED APPLICATIONS

This application claims priority to and the benefit of provisional patent application Ser. No. 61/369,425, filed on 30 Jul. 2010, the disclosure of which is incorporated herein by reference in its entirety.

### BACKGROUND

1. Field

The aspects of the present disclosure generally relate to solar energy collection. More particularly, the aspects of the present disclosure relate to a modular solar panel racking system.

2. Description of Related Art

Solar panels are used for harvesting solar energy. Generally, photovoltaic systems, also referred to as solar panels, are attached to a supporting structure and mounted on or in areas that have direct access to sunlight. Some typical areas for mounting solar panels can include the roofs of houses, tops of buildings, the ground or other large, open areas, that have unobstructed access to direct sunlight.

Solar panel systems generally include one or more photovoltaic modules that are arranged in arrays. The modules or panels are attached to a supporting surface and interconnected with electrical wiring to switches, inverters, battery chargers and other electrical components that are typically associated with solar systems or farms.

Photovoltaic modules typically consist of a photovoltaic module laminate and they may also include a frame. The photovoltaic module laminate is generally an assembly of crystalline or amorphous semiconductor devices electrically interconnected and encapsulated between a transparent front cover of glass or plastic and a back cover. The photovoltaic module will include electrical conductors exiting the laminate edge or back cover which conduct the solar generated current through the electrical circuit including the photovoltaic module. The back cover of the module can be an electrical insulating material that is impervious to moisture, and is often made of flexible Teller and/or other foil, film or rigid glass or plastic, for example.

For photovoltaic modules that incorporate a frame, the frame often consists of multiple aluminum extrusion elements which are assembled to surround the laminate, and are mechanically interconnected at the corners. The frame sections often include a channel to capture the laminate, which can be filled with a sealant during the frame assembly procedure. The sealant, often a butyl compound in the form of a gun able caulk, tape or putty, acts to promote the sealing of the edge of the laminate, to provide an adhesive attachment between the frame and the laminate, and to provide a cushion to protect the laminate edge from mechanical damage.

Typically, conventional solar panels can only be installed on dry land surfaces of earth, such as the ground or buildings. Due to the size requirements of the systems, the panels are required to be part of the assembly and attachments are incorporated on the panels so that the panels can be attached to the support structures. This can make the systems difficult to assemble. The added time and parts needed to make these connections adds to the time to assemble and cost of the assembled systems. Further these added parts or clamps create additional points of potential failure in the construction of the system.

Accordingly, it would be desirable to provide a system that addresses at least some of the problems identified above.

### SUMMARY

As described herein, the exemplary embodiments of the present invention overcome one or more of the above or other disadvantages known in the art.

The aspects of the disclosed embodiments generally provide a modular solar rack system. In one embodiment, the system comprises a left side slide support and a right side slide support. A wind deflector is used to couple the left side slide support to the right side slide support to form a solar panel rack assembly. The wind deflector is suitably sized to position the right and left slide supports a pre-determined spaced-apart distance from each other. The distance is generally a factor of the dimensions, and in particular the width, of the solar panel to be installed. Each slide support includes a main support member that is suitably angled relative to a base member to optimize the harvesting of solar power by the installed solar panel from the sun. In one embodiment, each slide support includes a channel portion formed in the main support member. Each channel portion is generally configured to slidably receive an edge of a solar panel and allow the panel to engage the channel portion and slide to a position stop member at an end of the respective channel portion. The channel portion is suitably sized and configured to removably retain the solar panel in the assembly in a secure, but removable manner.

The aspects of the disclosed embodiment provide several advantages over current systems including the ability to modularize the solar panel rack system and being able to assemble the system without having the solar panels in place or attached to the support structures. The wind deflector appropriately spaces the support structures apart, and the solar panel(s) are received in the channels or track in each support structure or slide, as that term is generally used herein. The structure is typically made of a material such aluminum, although other such durable and lightweight materials are within the scope of consideration.

These and other aspects and advantages of the exemplary embodiments will become apparent from the following detailed description considered in conjunction with the accompanying drawings. It is to be understood, however, that the drawings are designed solely for purposes of illustration and not as a definition of the limits of the invention. Moreover, the drawings are not necessarily drawn to scale and that, unless otherwise indicated, they are merely intended to conceptually illustrate the structures and procedures described herein.

### BRIEF DESCRIPTION OF THE DRAWINGS

In the drawings:

FIG. 1 is a perspective view of one embodiment of a solar panel racking system incorporating aspects of the present disclosure;

FIG. 2 is a left side, perspective view of the solar panel racking system assembly shown in FIG. 1;

FIG. 3 is a rear view of the solar panel racking system shown in FIG. 1;

FIG. 4 is a front view of an embodiment of the solar panel racking system shown in FIG. 1;

FIG. 5A is a perspective view of one embodiment of a slide support structure for the solar panel racking system of the present disclosure;

FIG. 5B is a detail view of a portion of the slide support structure shown in FIG. 5A;

FIG. 5C is a right side view of the slide support shown in FIG. 5A;

FIG. 5D is a top view of the slide support shown in FIG. 5A;

FIG. 5E is a perspective view of one embodiment of the slide support shown in FIG. 5A;

FIG. 5F is a right side view of one embodiment of the slide support shown in FIG. 5A;

FIG. 5G is a rear view of one embodiment of the slide support shown in FIG. 5A;

FIG. 5H is a detailed view of the slide support shown in FIG. 5G;

FIG. 5I is a bottom view of one embodiment of the slide support shown in FIG. 5A;

FIG. 5J is a rear view of one embodiment of a right slide support;

FIG. 5K is a perspective view of one embodiment of a right slide support;

FIG. 5L is a perspective view of one embodiment of the slide support of FIG. 5A.

FIG. 6 illustrates various views of a 10 degree solar panel racking system incorporating aspects of the present disclosure;

FIG. 7 illustrates one embodiment of a wind deflector for a solar panel racking system incorporating aspects of the present disclosure;

FIG. 8 illustrates a detail view of one embodiment of the mounting and securing mechanism for securing the wind deflector shown in FIG. 7 to the solar panel racking system incorporating aspects of the present disclosure;

FIG. 9 illustrates a detail view of one embodiment of the wind deflector and solar panel securing mechanism for a solar panel racking system incorporating aspects of the present disclosure;

FIG. 10 is a front perspective view of a solar panel racking system incorporating aspects of the present disclosure.

### DETAILED DESCRIPTION OF THE EXEMPLARY EMBODIMENTS

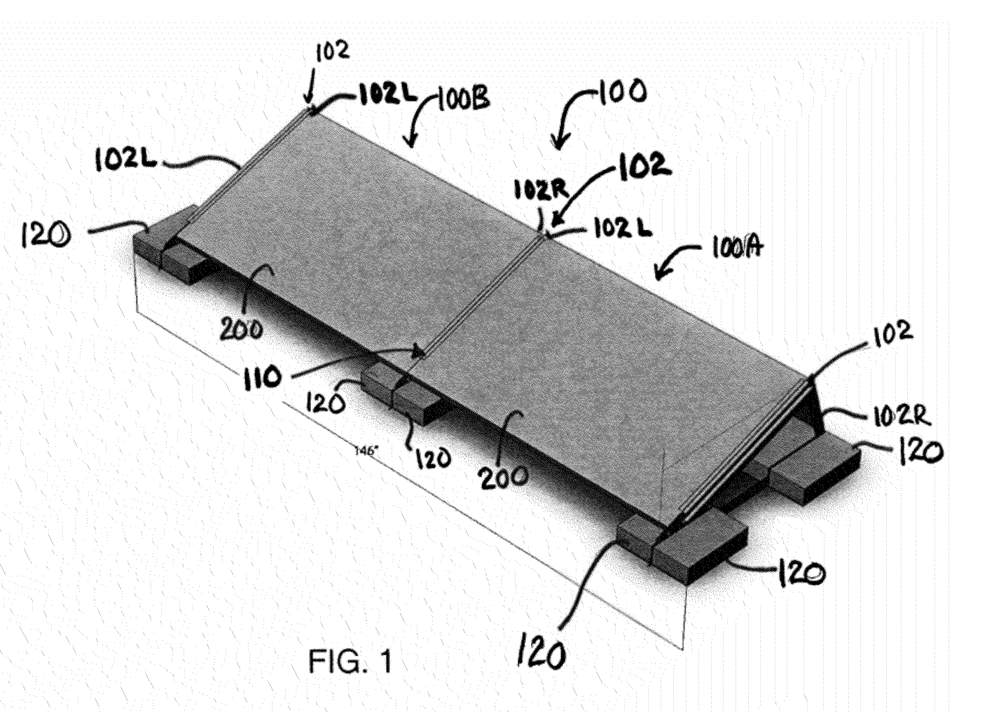

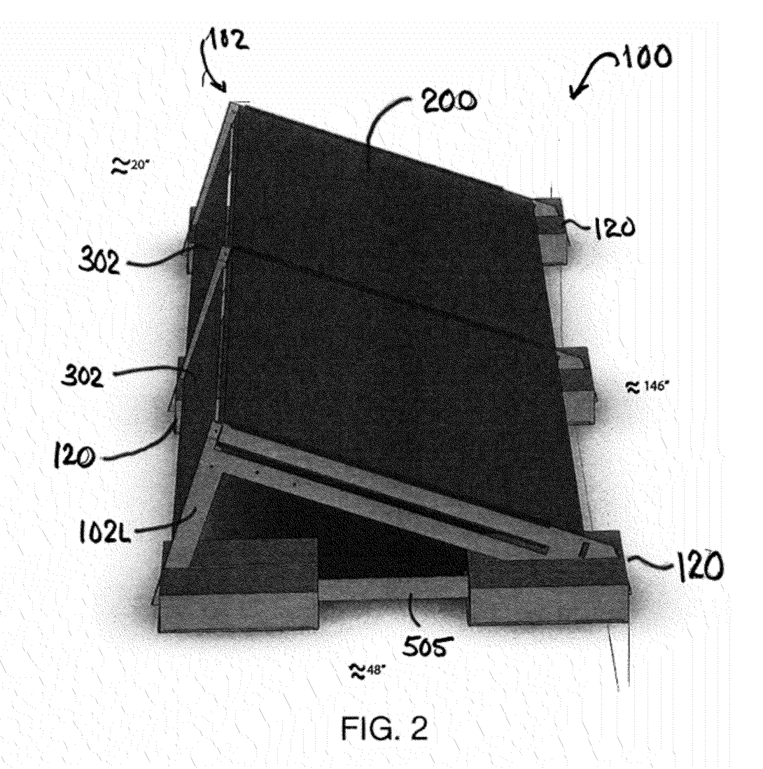

Referring now to FIGS. 1-3, a solar panel racking system in accordance with an exemplary embodiment of the invention is generally designated by reference numeral 100. The aspects of the disclosed embodiments are generally directed to a support and racking assembly for a modular solar panel system. The solar panel racking system 100 is generally configured for supporting one or more solar panels 200, also referred to as photovoltaic panels, for the harvesting of solar energy. The solar panel racking system 100 shown in FIG. 1 is modular in configuration and allows the modular build and quick installation of solar panels through an innovative “slide in” design. In one embodiment, the system 100 is a ballasted flat roof solar panel racking system that allows for the solar panels 200 to be installed into the racking system 100 after assembly of the rack and without any separate attachment to the panel 200.

Although FIGS. 1-3 show the solar panel racking system 100 with solar panels 200 installed, this is merely for illustration only and the aspects of the disclosed embodiments allow the racking system 100 to be assembled and made ready for use without the need to have the solar panels 200 on site. In other words, the rack portion or panel support structure of the racking system 100 can be pre-assembled without solar panels 200. The aspects of the disclosed embodiments offer the advantage that solar panels 200 can slide into receiving track assemblies or channels in each support structure 102 incorporated in the system 100 after the assembly thereof. The support structures 102 are generally configured to securely hold the panels 200 in place without the need for a separate attachment to the panel 200.

In the embodiment shown in FIG. 1, the solar panel racking system 100 comprises two solar panel support rack assemblies 100A, 100B, where each assembly 100A, 100B is essentially identical in configuration and structure. For purposes of the description herein, the same reference numerals will be used to describe like parts or portions of each assembly 100A, 100B and the system 100. Due to the modular nature of the system 100, the system 100 can be expanded in either direction, generally referred to herein as left and right along a substantially horizontal axis, to incorporate any number of additional solar panel support assemblies 100A, 100B.

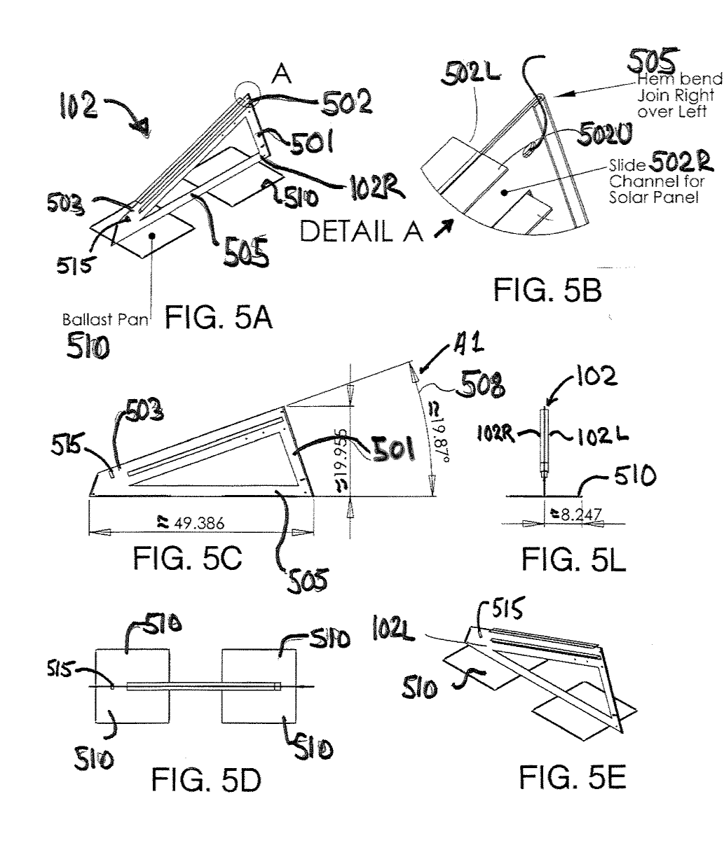

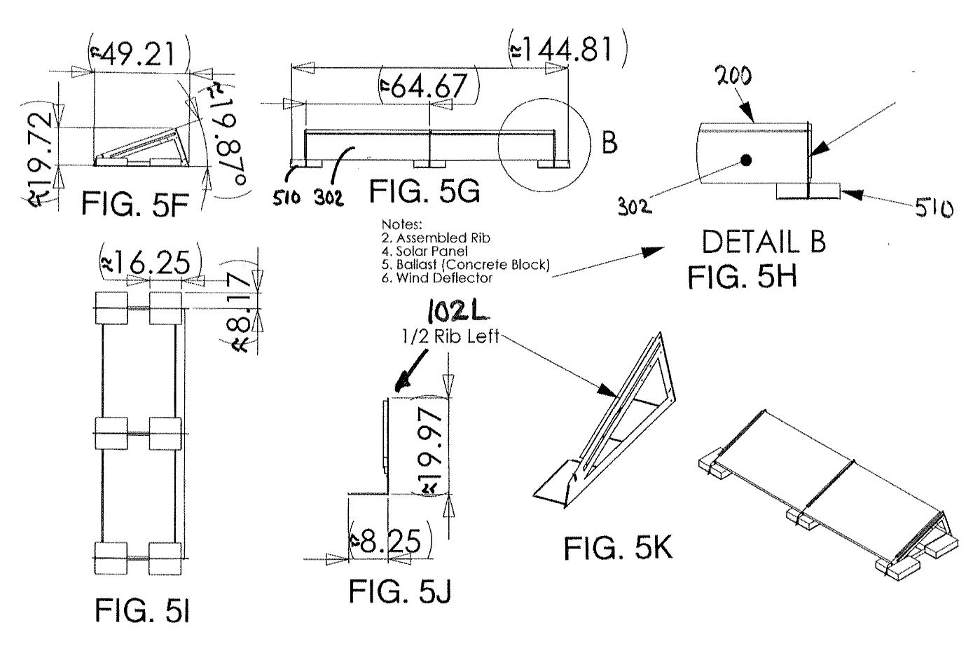

As shown in FIG. 1, each solar panel support assembly 100A, 100B, includes a support structure or rib assembly 102 at either end of each respective assembly 100A, 100B. As will be described with respect to FIG. 5A, each support structure 102 generally comprises a right support structure or rib 102R and a left support structure or rib 102L. The two panel support assemblies 100A, 100B are joined together at point 110 by connecting the respective rib supports 102L and 102R together to form the rib support structure 102.

In one embodiment, referring to FIGS. 5A and 5B, the each rib support structure or member 102R, 102L is a three-sided member generally comprising arms 501, 503, and 505. Arm 505 is the base arm for mounting on the ground structure, while arm 503 is the support arm for supporting the solar panel 200. Arm 501 is connected between the base arm 505 and the support arm 503.

In one embodiment, the support arm 503 includes a receiving track or slide channel 502 for receiving an edge of the solar panel 300. As is shown in FIG. 5B, the channel 502 has an upper member 502U and a lower member 502L. The members 502U, 502L are suitably spaced apart to accommodate an edge of the solar panel 200. The width of each member 502U, 502L is also of a suitable size so that the edge of the solar panel is securely received and maintained within the channel 502 without interfering with the solar collection or efficiency of the respective panel 200. A stop member 515 can be located on arm 503 to limit the travel of, and appropriately position the solar panel 200 within the channel 502.

In one embodiment, the rib support 102 is a two piece structure, with a right support 102R having a slide channel facing to the left (see FIG. 5K) and a left support 102L having a slide channel facing to the right (see FIG. 5A). As is shown in FIG. 5B, each rib support member 102L, 102R can be a sheet of folded metal that can be joined together, using for example a hem bend 525. In alternate embodiments, any suitable mechanism can be used to join a right rib support 102R to a left rib support 102L. When the two members (or sides) 102L, 102R are joined, they comprise the single support member 102 with a slide channel 502 on either side, referred to herein as left facing channel member 502L and right facing channel member 502R. It is noted that these designations are merely for descriptive purposes, and that the relative orientation of each support member 102L and 102R and the respective channels 502 will depend on its positioning relative to the remainder of the assembly 100A, 100B and the respective solar panels 200.

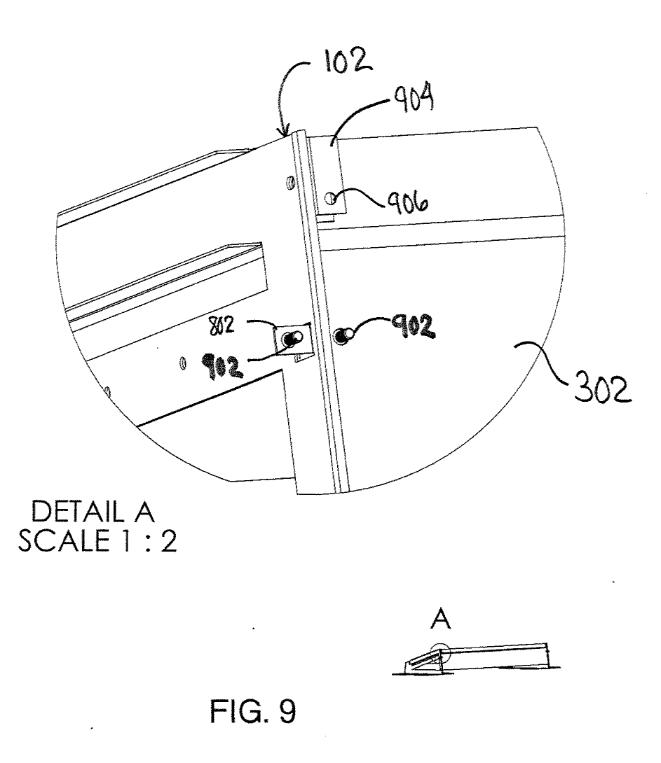

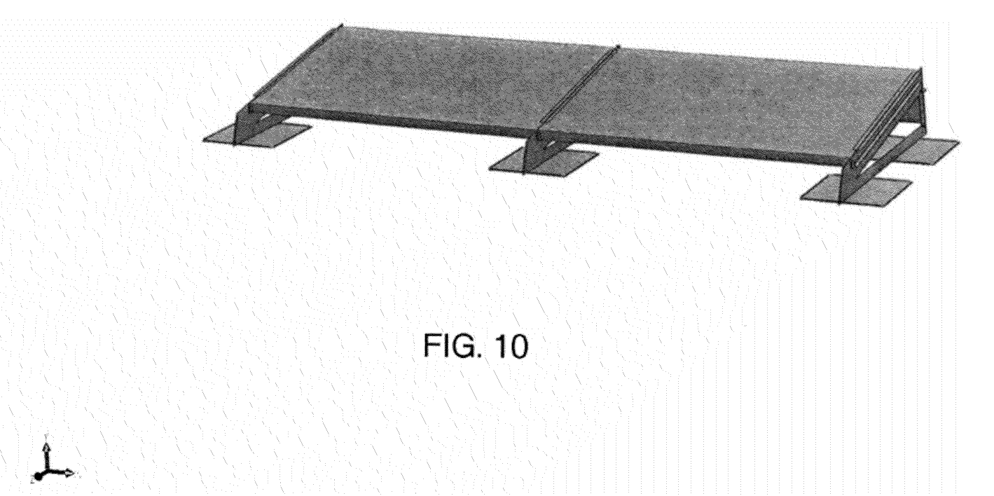

Referring to FIG. 9, in one embodiment, the panels 200 can be held in place by a combination bracket 904 that also supports a ground lug 906. The ground lug is used to receive a ground wire that is run along the back of all of the modules. This arrangement reduces the number of assembly components required in the solar rack system decreasing cost and time to assemble.

When a left support 102L is joined to a right support 102R as is shown in FIG. 5L, the left facing channel 502L and the right facing channel 502R are each configured to receive edges of different, or adjacent, solar panels 200. Each side edge of the solar panel 200 is configured to be slidably and removably retained in and between a left facing channel 502L and aright facing channel 502R. Additional supports 102L, 102R, or the combined support 102, can be added to the system 100 to expand the system 100 and add more solar panels and modules 100A, 100B.

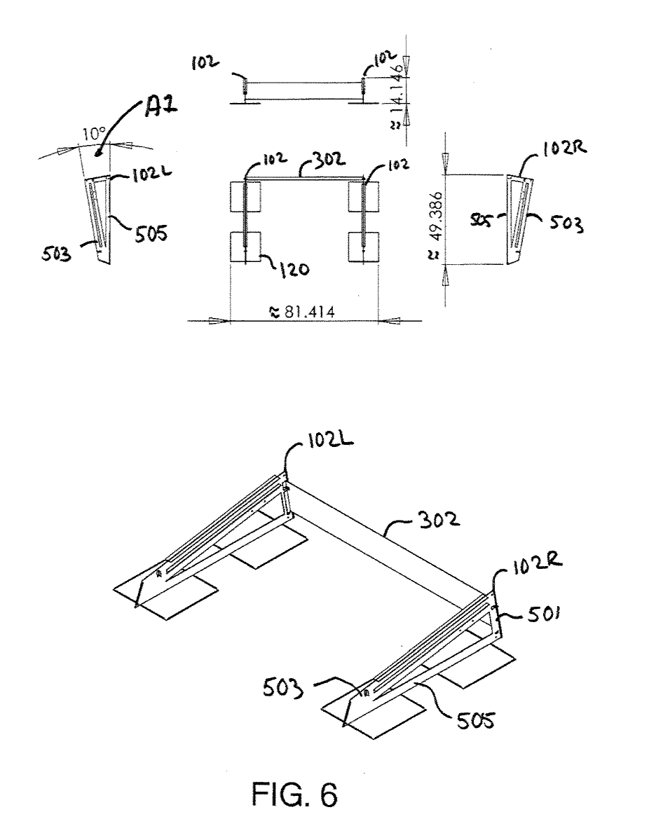

Referring to FIG. 5C, in one embodiment, the members 501, 503 and 505 are suitably configured so that an angle of approximately 20 degrees is formed by the intersection 508 of the members 503 and 505. Although an approximate angle of 20 degrees is described herein, in alternate embodiments, any suitable angle can be used. For example, in one embodiment, the angle can be in the range of approximately 5 degrees to approximately 60 degrees, inclusive, depending upon a number of factors including the presence and position of the sun relative to the earth. FIG. 6 illustrates an embodiment where the angle A1 is approximately 10 degrees.

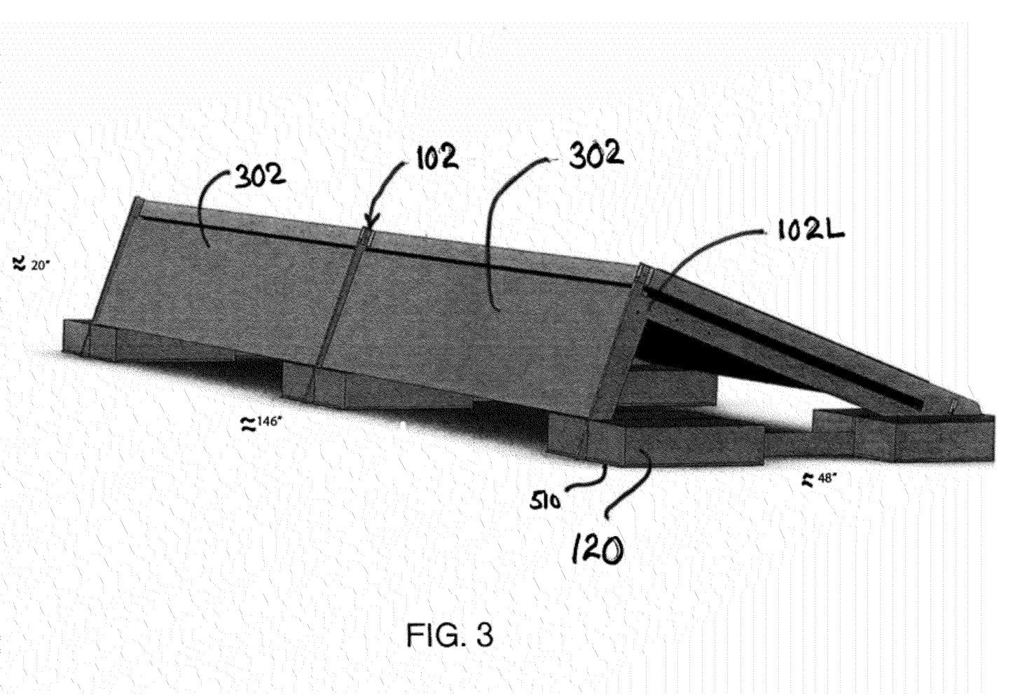

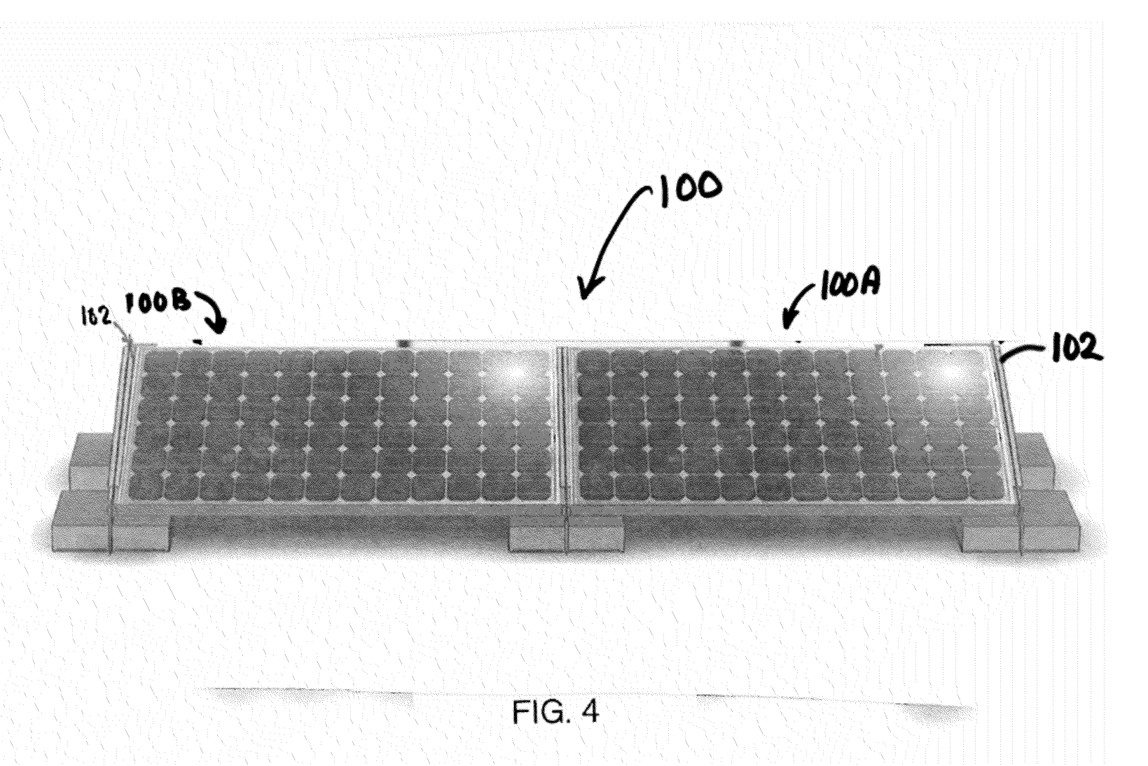

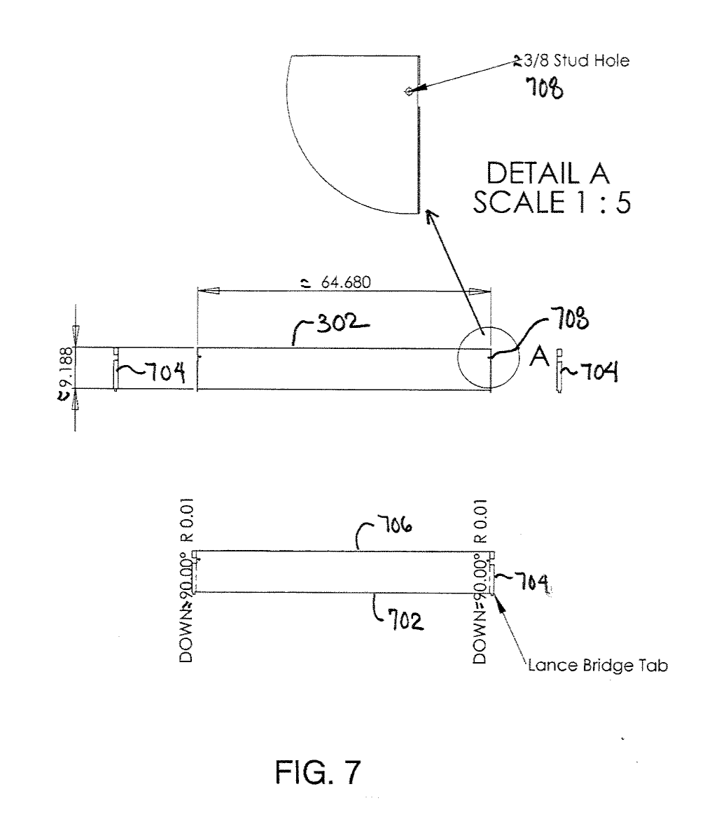

In one embodiment, as illustrated in FIG. 3, a left rib support member 102L is attached to a right rib support member 102R by a wind deflector 302, as is shown in FIG. 3. The wind deflector 302 is generally configured to space apart the rib support members 102L, 102R in a pre-determined relationship. The wind deflector's purpose is to divert the flow of coming from behind the solar panel and prevent the force of air from lifting or moving the racking and or solar panels. The wind deflector 302 is generally configured to redirect the air upwards and away from the racking system. FIG. 7 illustrates one embodiment of a wind deflector 302. As shown in FIG. 7, in one embodiment, the wind deflector is approximately 64 inches in length and 9 inches high. In alternate embodiments, the wind deflector 302 can comprise any suitable length and height.

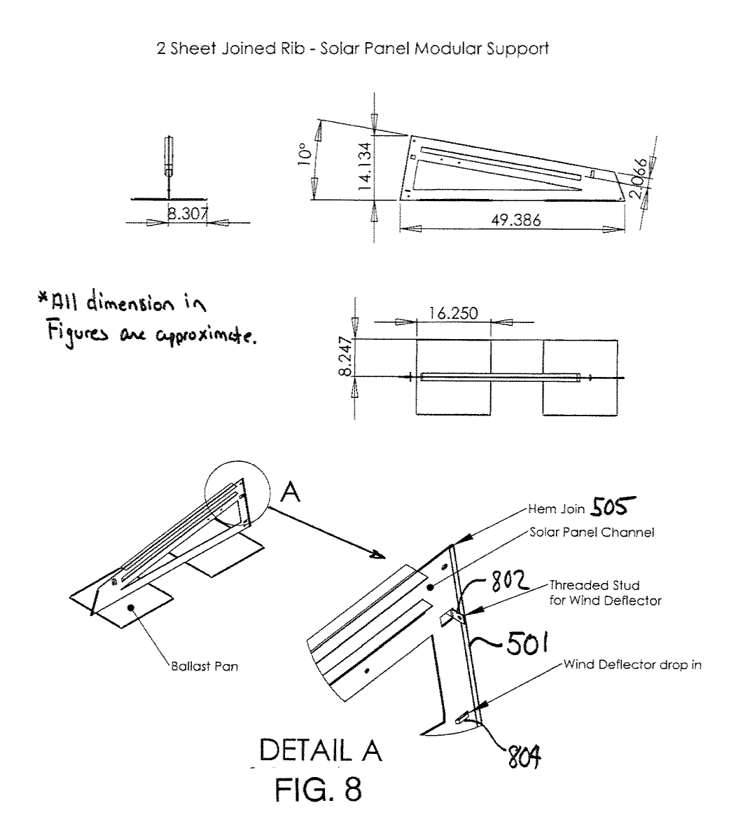

In one embodiment, referring to FIGS. 7 and 8, a lower portion 702 of the wind deflector 302 can be secured to each support 102 using a tab device 704, which in this example is a Lance Bridge tab. The tab 704 is received in a suitable receiver 804 on the support 102. An upper portion 706 of the wind deflector 302 can include a hole 708 in each corner for receiving a threaded screw or bolt to secure the wind deflector 302 to each support 102. In one embodiment, as is shown in FIGS. 8 and 9, the support 102 can include a flange 802 that includes a threaded stud 902 for engagement with the hole 708. A nut or other fastener can secure the wind deflector 302 to the threaded stud 902. In alternate embodiments, any suitable devices can be used for securing the wind deflector 302 to each support 102.

Referring to FIGS. 1-3, in one embodiment, each rack module 100A, 100B is generally configured to be held in place by one or more ballasts 120. In one embodiment, the ballasts 120 comprise concrete blocks. In alternate embodiments, the ballasts 120 can comprise any suitable material or structure for holding each rack module 110A, 100B securely in place, other than including concrete blocks. As is shown for example in FIG. 5A, each rib support member 102L, 102R includes a ballast pan 510 at each end of member 505. A rib support member 102 will have a total of four ballast pans 510, although in alternate embodiments, any suitable number of ballast pans 510 can be used.

In one embodiment, each rack module 100A, 100B is comprised of aluminum, although in alternate embodiments any suitable material can be used that is generally lightweight, durable and is configured to support the weight of a solar panel 200 as mounted in a channel or track therein. The dimensions shown in the drawings are merely approximations for exemplary purposes. In alternate embodiments, the relative sizing of each component of the system 100 and the overall dimensions can be of any suitable size, proportion and ranges to accommodate the different sizes and configurations of solar panels.

The aspects of the disclosed embodiments generally provide a ballasted flat roof solar panel racking system. The system is modular in configuration and can be suitably sized to accommodate any number of solar panels. Each rack assembly 100A, 100B includes a pair of slide supports 102L, 102R, on each side of the assembly respectively. The combination of a left support 102L and a right support 102R comprises a sliding support assembly 102. The combination of a pair of sliding supports 102L, 102R is fitted or connected together by a wind panel. The system of the disclosed embodiments can be pre-assembled, without the need for attachment to a panel. Each solar panel can be fitted or installed in the system 100 after the assembly of the system 100.

Thus, while there have been shown, described and pointed out, fundamental novel features of the invention as applied to the exemplary embodiments thereof, it will be understood that various omissions and substitutions and changes in the form and details of devices illustrated, and in their operation, may be made by those skilled in the art without departing from the spirit of the invention. Moreover, it is expressly intended that all combinations of those elements and/or method steps, which perform substantially the same function in substantially the same way to achieve the same results, are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A racking system for a solar panel, comprising:
a solar panel support rack assembly, the solar panel support rack assembly being configured to be coupled to another solar panel support rack assembly, each solar panel support rack assembly comprising:
a first arm having a first end and a second end, the first arm configured to be coupled to a base structure;
a second arm having a first end and a second end, the first end of the second arm coupled to the first end of the first arm, the second arm being disposed at an angle from the first arm; and
a third arm having a first end and a second end, the first end of the third arm coupled to the second end of the first arm and the second end of the third arm coupled to the second end of the second arm;
the second arm comprising:
a first channel member and a second channel member, the first and second channel members being disposed on opposing sides of the second arm; and
a stop member at the first end.

2. The racking system of claim 1, wherein an angle between an intersection of the first end of the first member and the first end of the second member is approximately 20 degrees.

3. The racking system of claim 1, further comprising a wind deflector coupled between the third arms of adjacent solar panel support rack assemblies.

4. The racking system of claim 1, further comprising a solar panel slidably retained between the first channel member and second channel member of adjacent solar panel rack assemblies.

5. The racking system of claim 1, wherein the base structure coupled to the first arm comprises a ballast structure.
